(19) United States
(12) Patent Application Publication
(10) Pub. No.: US 2026/0059900 A1
(43) Pub. Date: Feb. 26, 2026

(54) PHOTOELECTRIC PACKAGING STRUCTURE, MANUFACTURING METHOD, AND CAMERA MODULE

(71) Applicant: TRIPLE WIN TECHOLOGY(SHENZHEN) CO. LTD., Shenzeh (CN)

(72) Inventors: HSIN-YEN HSU, New Taipei (TW); TZU-LI FENG, New Taipei (TW); HUNG-TA LI, New Taipei (TW); YI-MOU HUANG, New Taipei (TW)

(21) Appl. No.: 19/249,055

(22) Filed: Jun. 25, 2025

(30) Foreign Application Priority Data
Aug. 22, 2024 (CN) 202411159128.2

(51) Int. Cl. H10F 77/00; H04N 23/55

(52) U.S. Cl. CPC H10F 77/933; H04N 23/55

(57) ABSTRACT

A photoelectric packaging structure, manufacturing method, and camera module are provided. The structure includes a plastic packaging module, a photosensitive chip, and a substrate module. The plastic packaging module includes a packaging body for covering the photosensitive chip. The substrate module includes a dielectric layer and a first multilayered wiring structure having a first and a second wiring layer. The first wiring layer includes a first conductive portion and a first conductive wiring pattern. One side of the first conductive portion contacts the connection pad of the photosensitive chip. The second wiring layer includes a second conductive portion and a second conductive wiring pattern. The second conductive wiring pattern is electrically connected to another side of the first conductive portion. The first and second conductive portions constitute a first conductive channel. The photosensitive chip is electrically connected to the first and second wiring layers through the first conductive channel.

### CROSS-REFERENCE TO RELATED APPLICATION

This application claims the benefit and priority to Chinese Patent Application Serial No. 202411159128.2, filed on August 22, 2024, entitled “PHOTOELECTRIC PACKAGING STRUCTURE, MANUFACTURING METHOD, AND CAMERA MODULE”, and the content of which is hereby fully incorporated by reference.

### FIELD

The subject matter herein generally relates to semiconductor packages, and more particularly, to a photoelectric packaging structure, a manufacturing method of the photoelectric packaging structure, and a camera module with the photoelectric packaging structure.

### BACKGROUND

Camera modules may include circuit boards and photosensitive chips mounted on the circuit boards. The photosensitive chip may be connected to conductive pads of the circuit board through a wire bonding technology or a flip-chip packaging technology.

However, a wire bonding tool needs a certain space between the photosensitive chip and the conductive pad of the circuit board when operated, which results in an increase in the lateral size between the photosensitive chip and the conductive pad. Furthermore, the flip-chip packaging requires the circuit board to have high flatness and symmetrically distributed solder pads, resulting in low universality. Improvements in the art are desired

### BRIEF DESCRIPTION OF THE DRAWINGS

FIG. 1 is a block diagram of a camera module according to an embodiment of the present disclosure.

FIG. 2 is a cross-sectional view of a photoelectric packaging structure of the camera module shown in FIG. 1.

FIG. 3 is a cross-sectional view of a photoelectric packaging structure according to another embodiment of the present disclosure.

FIG. 4 is a cross-sectional view showing a packaging body covering a photosensitive chip according to an embodiment of the present disclosure.

FIG. 5A is a cross-sectional view showing a first insulating layer and a first wiring layer formed on the packaging body shown in FIG. 4.

FIG. 5B is diagrammatic view of the structure shown in FIG. 5A.

FIG. 6A is a cross-sectional view showing a second insulating layer and a second wiring layer formed on the first wiring layer shown in FIG. 5A.

FIG. 6B is diagrammatic view of the structure shown in FIG. 6A.

FIG. 7 is a cross-sectional view showing a hollow channel defined in the packaging body shown in FIG. 6A and a conductive material filled in the hollow channel.

FIG. 8 is a cross-sectional view of a photoelectric packaging structure according to another embodiment of the present disclosure.

FIG. 9 is a cross-sectional view of a photoelectric packaging structure according to yet another embodiment of the present disclosure.

FIG. 10 is a cross-sectional view of a photoelectric packaging structure according to yet another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

### First embodiment

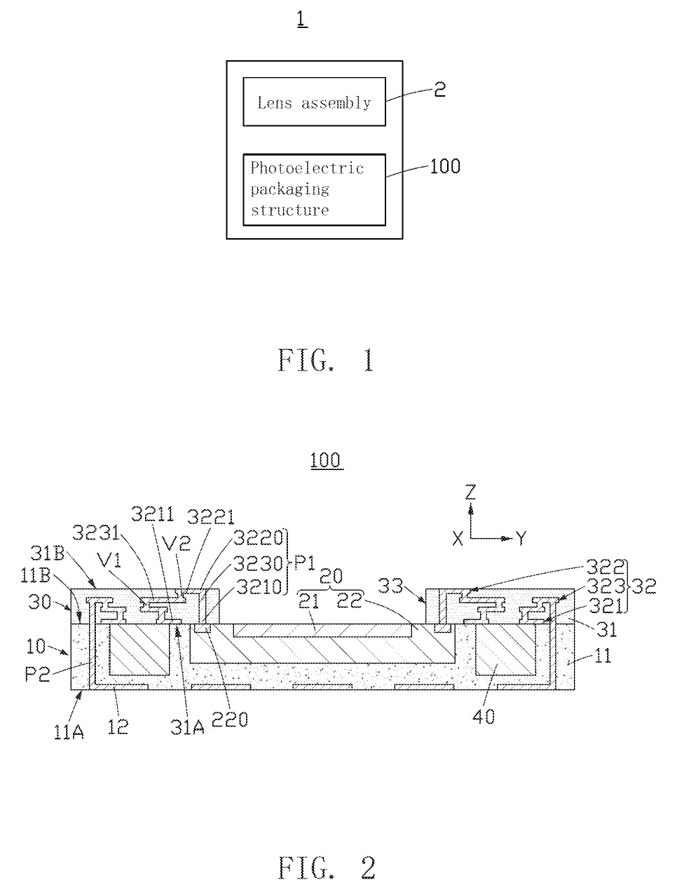

Referring to FIG. 1, a camera module 1 is provided according to an embodiment of the present disclosure. The camera module 1 includes a lens assembly 2 and a photoelectric packaging structure 100. The lens assembly 2 has an optical path for an external light beam to pass through. The photoelectric packaging structure 100 receives the external light beam passing through the lens assembly 2 to form an optical signal, and then converts the optical signal into electrical signal to realize photoelectric conversion.

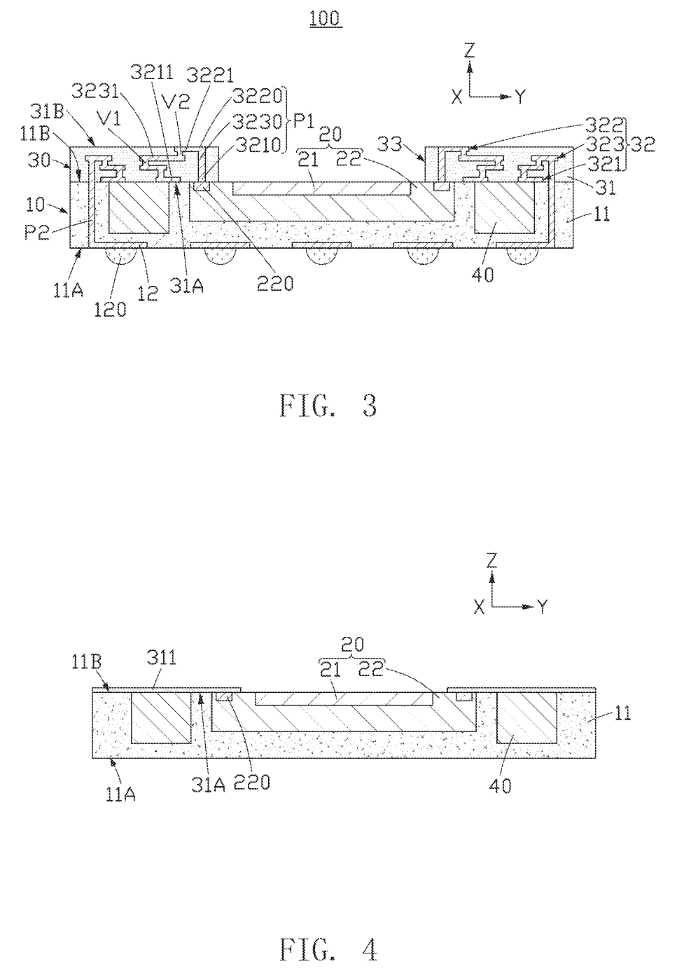

Referring to FIG. 2, the photoelectric packaging structure 100 includes a plastic packaging module 10, a photosensitive chip 20, and a substrate module 30. The plastic packaging module 10 includes a packaging body 11. The packaging body 11 includes a first surface 11A and a second surface 11B opposite to each other. In some embodiments, the packaging body 11 includes at least one of an epoxy resin and a phenolic resin.

The photosensitive chip 20 is embedded in the packaging body 11. The packaging body 11 at least covers a sidewall of the photosensitive chip 20, and the packaging body 11 can improve the stability and reliability of the photosensitive chip 20. The photosensitive chip 20 includes a photosensitive area 21 and a non-photosensitive area 22 connected to each other. Each of the photosensitive area 21 and the non-photosensitive area 22 is exposed from the second surface 11B. The photosensitive area 21 receives the optical signal formed by the external light beam passing through the lens assembly 2, and then converts the optical signal into the electrical signal. The non-photosensitive area 22 may surround the photosensitive area 21. A connection pad 220 (such as an aluminum pad) may be provided on the non-photosensitive area 22. In some embodiments, the first surface 11A of the packaging body 11 may be located below the photosensitive chip 20, that is, the packaging body 11 may also cover the bottom surface of the photosensitive chip 20.

The plastic packaging module 30 is located on the second surface 11B. The plastic packaging module 30 includes a dielectric layer 31 and a first multilayered wiring structure 32. The dielectric layer 31 includes a third surface 31A facing the second surface 11B and a fourth surface 31B opposite to the third surface 31A. The lens assembly 2 may be located on the fourth surface 31B. The first multilayered wiring structure 32 is formed in the dielectric layer 31, and includes a first wiring layer 321, a second wiring layer 322, and a third wiring layer 323. The first wiring layer 321, the second wiring layer 322, and the third wiring layer 323 are stacked with each other along a thickness direction Z of the substrate module 30. The first wiring layer 321, the second wiring layer 322, and the third wiring layer 323 are electrically connected to each other. The first wiring layer 321 and the second wiring layer 322 may be the outermost wiring layers. At least one third wiring layer 323 may be located between the first wiring layer 321 and the second wiring layer 322. That is, the first multilayered wiring structure 32 may include at least three wiring layers. It can be understood that in other embodiments, the first multilayered wiring structure 32 may also include two wiring layers stacked along the thickness direction Z of the substrate module 30. The first wiring layer 321 is exposed from the third surface 31A, and includes a first conductive wiring pattern 3211 and a first conductive portion 3210. Since the first conductive portion 3210 is exposed from the third surface 31A, it is convenient for one side of the first conductive portion 3210 to be in direct contact with the connection pad 220. A first direction X and a second direction Y are defined as different directions. In some embodiments, each of the first direction X and the second direction Y is perpendicular to the thickness direction Z of the substrate module 30. Therefore, at least a portion of the first conductive wiring pattern 3211 extends along the first direction X (as shown in FIG. 5B). The first direction X intersects with the second direction Y. In some embodiments, the first direction X is perpendicular to the second direction Y.

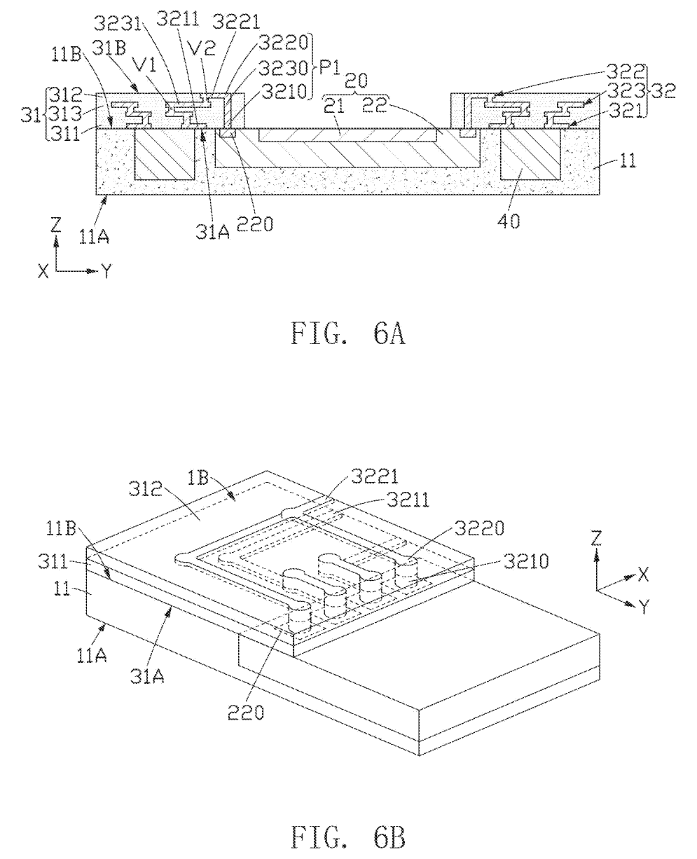

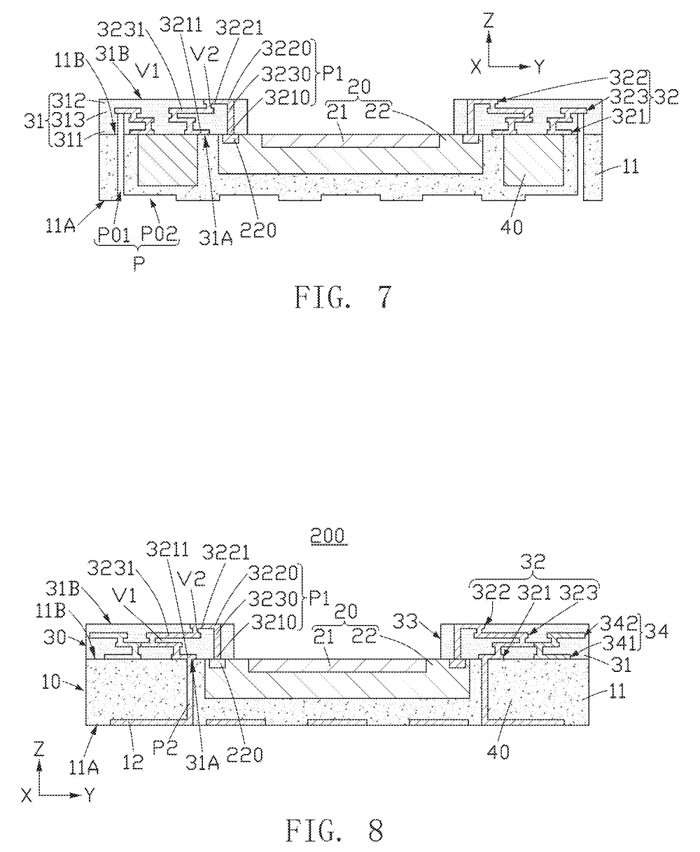

The second wiring layer 322 may be exposed from the fourth surface 31B, and include a second conductive wiring pattern 3221 and a second conductive portion 3220. A portion of the second conductive wiring pattern 3221 is electrically connected to the second conductive portion 3220, a portion of the second conductive wiring pattern 3221 is electrically connected to the first conductive wiring pattern 3211, and at least a portion of the second conductive wiring pattern 3221 extends along the second direction Y (as shown in FIG. 6B). The second conductive portion 3220 is electrically connected to another side of the first conductive portion 3210 away from the connection pad 220. At least the first conductive portion 3210 and the second conductive portion 3220 cooperatively constitute a first conductive channel P1 extending along the thickness direction Z of the substrate module 30. The first conductive channel P1 may extend through the third surface 31A and the fourth surface 31B. Therefore, the photosensitive chip 20 is electrically connected to the first wiring layer 321 and the second wiring layer 322 through the connection pad 220 and the first conductive channel P1.

Through a Redistribution Laye (RDL) process, the second conductive wiring pattern 3221 redistributes the connection pad 220 of the non-photosensitive area 22. Since the first conductive wiring pattern 3211 is electrically connected to the second conductive wiring pattern 3221, the first conductive wiring pattern 3211 further redistributes the connection pad 220 of the non-photosensitive area 22, thereby transmitting the electrical signal of the photosensitive chip 20 to an external component (such as a system terminal, a circuit board, or a chip) through the first multilayered wiring structure 32. Since the extension direction of at least a portion of the first wiring layer 321 is different from that of at least a portion of the second wiring layer 322, it is beneficial to improve the wiring flexibility and density, thereby enhancing the flexibility and reliability of the photoelectric packaging structure 100. In some embodiments, the first conductive wiring pattern 3211 extends both along the first direction X and the second direction Y, respectively. The second conductive wiring pattern 3221 also extends both along the first direction X and the second direction Y, respectively, thereby further improving the wiring flexibility and density. In some embodiments, the first multilayered wiring structure 32 includes a conductive material, and the conductive material may be a conductive ink or a metal material. The conductive ink may include an element selected from a group consisting of silver, platinum, gold, copper, nickel, aluminum, and any combination thereof. The metal material may be silver, copper, or gold. In some embodiments, the dielectric layer 31 may include a resin selected from a group consisting of epoxy resin, polyphenylene ether, polyimide, polyethylene terephthalate, and polyethylene naphthalate.

In some embodiments, the third wiring layer 323 includes a third conductive wiring pattern 3231 and a third conductive portion 3230. Two sides of the third conductive portion 3230 are connected to the first conductive portion 3210 and the second conductive portion 3220, respectively. The first conductive portion 3210, the second conductive portion 3220, and the third conductive portion 3230 cooperatively constitute the first conductive channel P1. At least a portion of the third conductive wiring pattern 3231 extends along the first direction X or the second direction Y. The third conductive wiring pattern 3231 may be electrically connected to the first conductive wiring pattern 3211 through a first via V1. The third conductive wiring pattern 3231 may also be electrically connected to the second conductive wiring pattern 3221 through a second via V2, thereby achieving electrical connection among different wiring patterns.

The substrate module 30 may further include a through hole 33 in the dielectric layer 31. The through hole 33 extends through the third surface 31A and the fourth surface 31B, and the through hole 33 is spaced from the first multilayered wiring structure 32. The photosensitive area 21 of the photosensitive chip 20 is exposed from the through hole 33. The photosensitive area 21 can receive the optical signal formed by the external light beam sequentially passing through the lens assembly 2 and the through hole 33, and then convert the optical signal into the electrical signal.

In the photoelectric packaging structure 100 of the present disclosure, the connection pad 220 is in direct contact with the second conductive portion 3220 of the second wiring layer 321, and electrically connected to the second wiring layer 322 through the first conductive channel P1. That is, the connection pad 220 is in direct contact with the first conductive channel P1, and an additional connection medium is not needed between the connection pad 220 and the first conductive channel P1. Compared to the existing wire bonding process, the signal conduction path in the first conductive channel P1 is shorter, which is beneficial for improving the quality of signal transmission. Furthermore, there is no need to reserve the space required for wire bonding tool, which is beneficial for reducing the lateral size of the photoelectric packaging structure 100 and conducive to the miniaturization of the photoelectric packaging structure 100. Meanwhile, compared to the existing flip-chip packaging process, the present disclosure is not limited to using a photosensitive chip 20 with symmetrically distributed solder pads, and is also not limited by the size of metal balls that results in excessively high requirements for the flatness of the substrate. Moreover, since the extension direction of at least a portion of the first wiring layer 321 is different from that of at least a portion of the second wiring layer 322, it is beneficial to improve the wiring flexibility and density, thereby enhancing the flexibility and reliability of the photoelectric packaging structure 100. In addition, since the lens assembly 2 is located on the fourth surface 31B, the lens assembly 2 also protects the photosensitive area 21 of the photosensitive chip 20, thereby reducing damages to the photosensitive area 21 under an external force. Since the fourth surface 31B has a high flatness, it is also conducive to installing the lens assembly 2 on the fourth surface 31B and increasing the connecting area between the lens assembly 2 and the substrate module 30, thereby improving the connecting strength between the lens assembly 2 and the substrate module 30.

In some embodiments, the connection pad 220 and the first multilayered wiring structure 32 are made of a same conductive material. For example, each of the connection pad 220 and the first multilayered wiring structure 32 is made of silver. Due to the use of the same conductive material, it is beneficial to further improve the quality of signal transmission.

In some embodiments, the plastic packaging module 10 further includes a second conductive channel P2 and a first solder pad 12. The second conductive channel P2 is formed in the packaging body 11 and a portion of the dielectric layer 31. The second conductive channel P2 extends through the first surface 11A and the second surface 11B of the packaging body 11. The first solder pad 12 is exposed from the first surface 11A. Two ends of the second conductive channel P2 are connected to one wiring pattern and the first solder pad 12, respectively. For example, when the first multilayered wiring structure 32 includes the third wiring layer 323, the two ends of the second conductive channel P2 are connected to the third conductive wiring pattern 3231 and the first solder pad 12, respectively. That is, one end of the second conductive channel P2 passes through the first conductive wiring pattern 3211 and is connected to the third conductive wiring pattern 3231. By exposing the first solder pad 12 from the first surface 11A, it facilitates the connection between the first solder pad 12 and the external component. As such, the electrical signal generated by the photosensitive chip 20 may be transmitted to the external components sequentially through the first conductive channel P1, the first multilayered wiring structure 32, the second conductive channel P2, and the first solder pad 12. That is, the first conductive channel P1 and the second conductive channel P2 cooperate with each other to deliver the electrical signal out of the first surface 11A. In some embodiments, each of the second conductive channel P2 and the first solder pad 12 includes a conductive material, and the conductive material may include a conductive ink or a metal material. The conductive ink may include an element from a group consisting of silver, platinum, gold, copper, nickel, aluminum, and any combination thereof. The metal material may be silver, copper, or gold. In some embodiments, the connection pad 220, the first multilayered wiring structure 32, the second conductive channel P2, and the first solder pad 12 are made of the same conductive material, thereby further improving the quality of signal transmission.

Referring to FIG. 3, in some embodiments, a solder ball 120 may also be provided on the first solder pad 12. The above external component may be installed on the solder ball 120, such that the electrical signal transmitted to the first solder pad 12 may further be transmitted to the external component through the solder ball 120. The solder ball 120 may be a tin ball.

As shown in FIG. 2, the photoelectric packaging structure 100 may further include a first electronic component 40 connected to the first conductive wiring pattern 3211. The packaging body 11 further covers the first electronic component 40. Through the RDL process, the first conductive wiring pattern 3211 redistributes the connection pad 220 of the non-photosensitive area 22 to transmit the electrical signal of the photosensitive chip 20 to the first electronic component 40, and then transmits the electrical signal from the first electronic component 40 to the external component. The first electronic component 40 may be a passive component or an active component. The passive component includes a resistor, a capacitor, etc. The active component includes a transistor, an integrated circuit, a picture tube, etc. In the embodiment, the first electronic component 40 is an active component.

A manufacturing method of the photoelectric packaging structure 100 in accordance with an embodiment. The method is provided by way of embodiments, as there are a variety of ways to carry out the method. The method can begin at step S1.

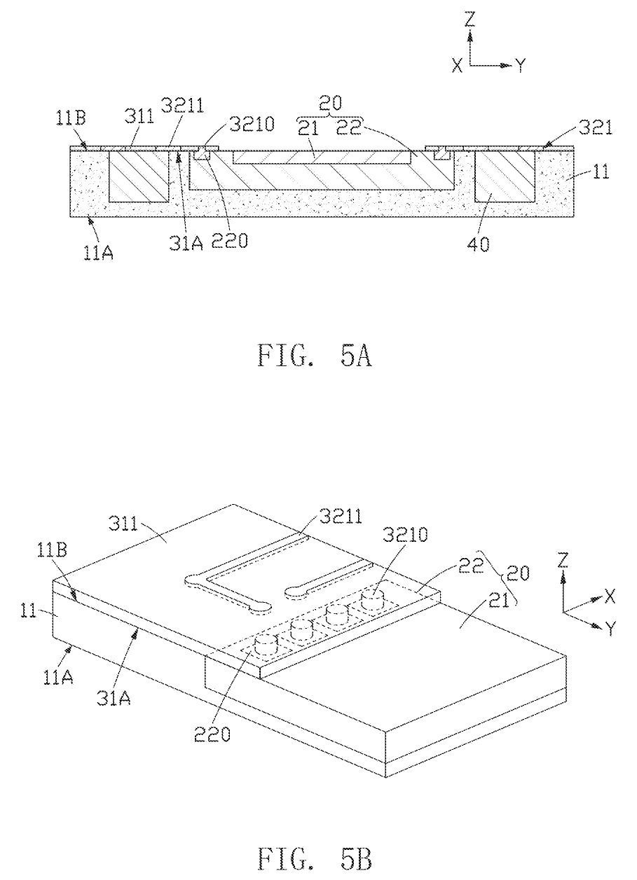

At step S1, referring to FIG. 4, a packaging body 11 covers the photosensitive chip 20. The packaging body 11 includes a first surface 11A and a second surface 11B opposite to each other. The photosensitive chip 20 includes a photosensitive area 21 and a non-photosensitive area 22 connected to each other. Each of the photosensitive area 21 and the non-photosensitive area 22 is exposed from the second surface 11B. A connection pad 220 is provided on the non-photosensitive area 22.

The packaging body 11 covers at least the sidewall of the photosensitive chip 20. In some embodiments, the first surface 11A may be located below the photosensitive chip 20, that is, the packaging body 11 may also cover the bottom surface of the photosensitive chip 20. The packaging body 11 may be formed through a molding process and has a high degree of flatness. The packaging body 11 may include at least one of an epoxy resin and a phenolic resin.

In some embodiments, after forming the packaging body 11, the packaging body 11 also covers the first electronic component 40, and a portion of the first electronic component 40 is exposed from the second surface 11B. The first electronic component 40 may be a passive component or an active component. The passive component includes a resistor, a capacitor, etc. The active component includes a transistor, an integrated circuit, a picture tube, etc. In the embodiment, the first electronic component 40 is an active component.

Step S2, referring to FIGS. 4 and 5A, a first insulating layer 311 is formed on the second surface 11B, and a first wiring layer 321 is formed in the first insulating layer 311. The first insulating layer 311 includes a third surface 31A facing the second surface 11B, and the first wiring layer 321 is exposed from the third surface 31A. The first wiring layer 321 includes a first conductive portion 3210 and a first conductive wiring pattern 3211. One side of the first conductive portion 3210 is in contact with the connection pad 220. As shown in FIG. 5B, at least a portion of the first conductive wiring pattern 3211 extends along the first direction X.

It can be understood that the structure located on another side of the photosensitive chip 20 in the second direction Y is omitted from FIG. 5B for clarity. In some embodiments, the first wiring layer 321 may be formed by defining a hollow wiring pattern in the first insulating layer 311 through laser and filling a conductive material in the hollow wiring pattern. The conductive material may be formed in the hollow wiring pattern by inkjet printing. It can be understood that the wiring pattern includes a pattern portion corresponding to the first conductive wiring pattern 3211 and a channel portion corresponding to the first conductive portion 3210. The conductive material of the first wiring layer 321 may be a conductive ink or a metal material. The conductive ink may include an element selected from a group consisting of silver, platinum, gold, copper, nickel, aluminum, and any combination thereof. The metal material may be silver, copper, or gold. In some embodiments, the first insulating layer 311 may include a resin selected from a group consisting of epoxy resin, polyphenylene ether, polyimide, polyethylene terephthalate, polyethylene naphthalate, and any combination thereof.

In some embodiments, when the first electronic component 40 is further provided in the packaging body 11, the first electronic component 40 is connected to the first conductive wiring pattern 3211.

Step S3, referring to FIG. 6A, a second insulating layer 312 is formed on the first insulating layer 311, and a second wiring layer 322 is formed in the second insulating layer 312 through a build-up process. The second wiring layer 322 includes a second conductive portion 3220 and a second conductive wiring pattern 3221. A portion of the second conductive wiring pattern 3221 is electrically connected to the second conductive portion 3220, a portion of the second conductive wiring pattern 3221 is electrically connected to the first conductive wiring pattern 3211, and at least a portion of the second conductive wiring pattern 3221 extends along the second direction Y (shown in FIG. 6B). The second conductive portion 3220 is electrically connected to another side of the first conductive portion 3210, and at least the first conductive portion 3210 and the second conductive portion 3220 cooperatively constitute a first conductive channel P1 extending along the thickness direction Z, such that the photosensitive chip 20 is electrically connected to the first wiring layer 321 and the second wiring layer 322 through the connection pad 220 and the first conductive channel P1.

It can be understood that the structure located on another side of the photosensitive chip 20 in the second direction Y is omitted from FIG. 6B for clarity. As shown in FIG. 6A, in some embodiments, the second wiring layer 322 may be formed by a manufacturing method similar to that of the first wiring layer 321. Before forming the second insulating layer 312 and the second conductive wiring pattern 3221, a third insulating layer 313 may first be formed on the first insulating layer 311, and a third wiring layer 323 may be formed in the third insulating layer 313 (the third insulating layer 313 and the third wiring layer 323 are omitted from FIG. 6B for clarity). The third wiring layer 323 includes a third conductive portion 3230 and a third conductive wiring pattern 3231. Two sides of the third conductive portion 3230 are electrically connected to the first conductive portion 3210 and the second conductive portion 3220, respectively, to cooperatively constitute the first conductive channel P1. At least a portion of the third conductive wiring pattern 3231 extends along the first direction X or the second direction Y. The third conductive wiring pattern 3231 is electrically connected to the first conductive wiring pattern 3211 through a first via V1, and the third conductive wiring pattern 3231 is electrically connected to the second conductive wiring pattern 3221 through a second via V2. The first wiring layer 321, the second wiring layer 322, and the third wiring layer 323 cooperatively constitute the first multilayered wiring structure 32. The first insulating layer 311, the second insulating layer 312, and the third insulating layer 313 may be made of a same material. The first insulating layer 311, the second insulating layer 312, and the third insulating layer 313 cooperatively constitute the dielectric layer 31. In other embodiments, the third insulating layer 313 and the third wiring layer 323 may also be omitted, that is, the first multilayered wiring structure 32 only includes two wiring layers.

In some embodiments, the above manufacturing method may further include the following steps.

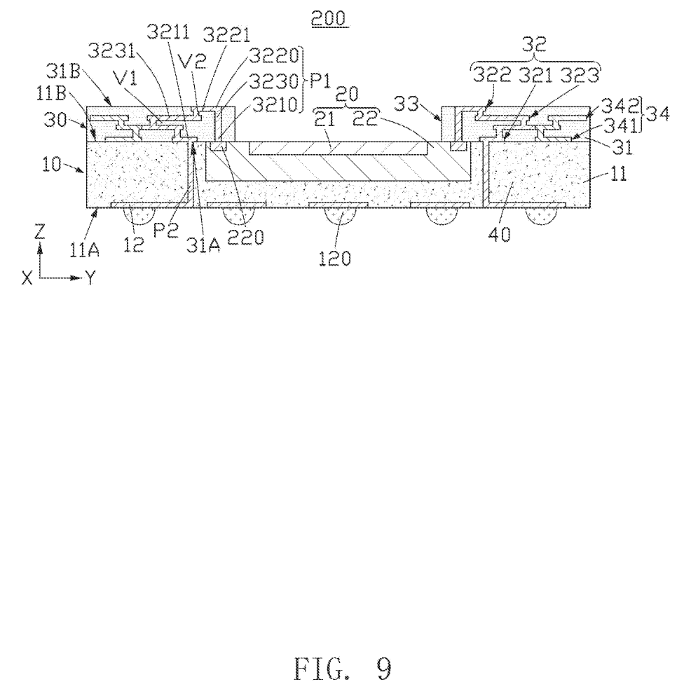

Step S4, referring to FIG. 7, a hollow channel P is defined in the packaging body 11 by laser. The hollow channel P includes a first channel portion P01 and a second channel portion P02 connected to each other. The first channel portion P01 extends through the first surface 11A and the second surface 11B along the thickness direction of the packaging body 11 (i.e., the thickness direction Z of the substrate module 30). The first channel portion P01 further extends to the third conductive wiring pattern 3231. The second channel part P02 is located on the first surface 11A.

Step S5, referring to FIG. 2, a conductive material is filled in the hollow channel P and solidified to obtain a second conductive channel P2 and a first solder pad 12. Two ends of the second conductive channel P2 are connected to one of the conductive wiring patterns of the first multilayered wiring structure 32 and the first solder pad 12, respectively. At this time, the photoelectric packaging structure 100 is obtained.

When the first multilayered wiring structure 32 includes the third wiring layer 323, the two ends of the second conductive channel P2 are connected to the third conductive wiring pattern 3231 and the first solder pad 12, respectively. That is, one end of the second conductive channel P2 passes through the first conductive wiring pattern 3211 and is connected to the third conductive wiring pattern 3231. As such, the electrical signal generated by the photosensitive chip 20 is transmitted to the external component sequentially through the first conductive channel P1, the first multilayered wiring structure 32, the second conductive channel P2, and the first solder pad 12. In the embodiment, steps S4 and S5 are executed after step S3. In other embodiments, steps S4 and S5 may also be executed after step S1. That is, the second conductive channel P2 and the first solder pad 12 are first formed in the packaging body 11, such that after forming the first wiring layer 321, one end of the second conductive channel P2 is connected to the first conductive wiring pattern 3211 of the first wiring layer 321.

In some embodiments, the conductive material may be filled in the hollow channel P through inkjet printing to obtain the second conductive channel P2 and the first solder pad 12. The conductive material may be a conductive ink or a metal material. The conductive ink may include an element selected from a group consisting of silver, platinum, gold, copper, nickel, aluminum, and any combination thereof. The metal material may be silver, copper, or gold. The hollow channel P may be completely filled with the conductive material to form the second conductive channel P2. In other embodiments, the inner wall of the hollow channel P is provided with a conductive layer formed by solidifying the conductive material, thereby forming the second conductive channel P2 that is hollow.

As shown in FIG. 3, in some embodiments, a solder ball 120 may also be formed on the first solder pad 12. The solder ball 120 may be a tin ball.

### Second embodiment

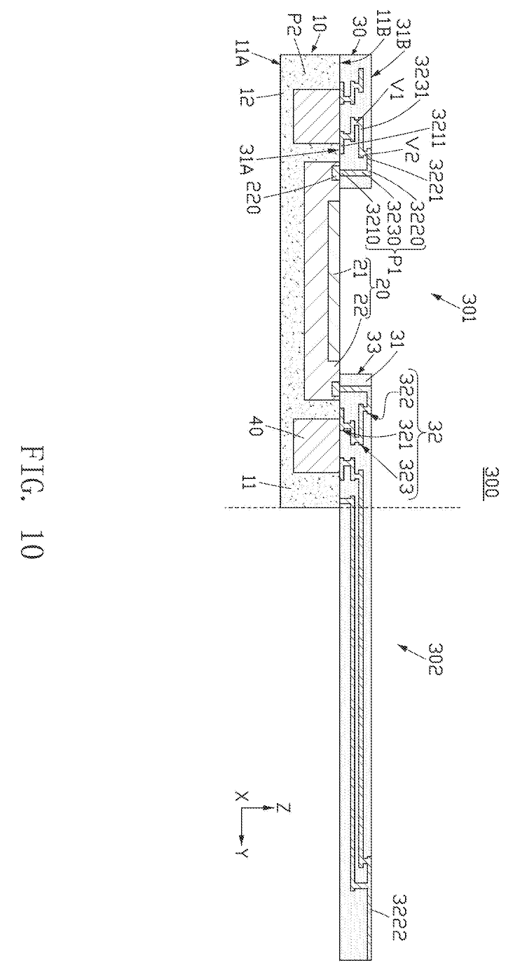

Referring to FIG. 8, a photoelectric packaging structure 200 is provided according to another embodiment of the present disclosure. The difference from the above photoelectric packaging structure 100 includes the position of the second conductive channel P2. Specifically, the second conductive channel P2 is located in the packaging body 11 and extends through the first surface 11A and the second surface 11B. The second conductive channel P2 does not extend into the dielectric layer 31. The two ends of the second conductive channel P232 are connected to the first conductive wiring pattern 3211 and the first solder pad 12, respectively. As shown in FIG. 9, in some embodiments, a solder ball 120 may also be formed on the first solder pad 12. The solder ball 120 may be a tin ball.

In some embodiments, the substrate module 30 may also include a second multilayered wiring structure 34 located in the dielectric layer 31. The second multilayered wiring structure 34 is electrically connected to the first multilayered wiring structure 32. The second multilayered wiring structure 34 constitutes a second electronic component. The second electronic component may be an active component or a passive component. The active component may include a transistor, an integrated circuit, or an image tube. The passive component may include a resistor, an inductor, a capacitor, etc. In the embodiment, the second electronic component is a passive component. In some embodiments, the second multilayered wiring structure 34 includes a conductive material, and the conductive material may be a conductive ink or a metal material. The conductive ink may include an element selected from a group consisting of silver, platinum, gold, copper, nickel, aluminum, and any combination thereof. The metal material may be silver, copper, or gold.

The present embodiment further provides a manufacturing method of the photoelectric packaging structure 200. The difference from the above manufacturing method in the first embodiment includes that when forming the first wiring layer 321 in step S2, a fourth wiring layer 341 may also be formed in the first insulating layer 311. When forming the third wiring layer 323 in step S3, a fifth wiring layer 342 may also be formed in the third insulating layer 313. As such, at least the fourth wiring layer 341 and the fifth wiring layer 342 cooperatively constitute the second electronic component. That is, the second electronic component is also formed through the build-up process.

Moreover, the hollow channel P, which is defined in step S4, is located in the packaging body 11 and extends through the first surface 11A and the second surface 11B. The hollow channel P does not extend into the dielectric layer 31. As such, after filling the hollow channel P with the conductive material in step S5, the two ends of the second conductive channel P2 are connected to the first conductive wiring pattern 3211 and the first solder pad 12, respectively.

### Third embodiment

Referring to FIG. 10, a photoelectric packaging structure 300 is provided according to yet another embodiment of the present disclosure. The difference from the above photoelectric packaging structure 100 includes the structure of the substrate module 30. Specifically, the substrate module 30 includes a first substrate region 301 and a second substrate region 302 connected to each other. Along the thickness direction Z of the substrate module 30, the first substrate region 301 overlaps with the plastic packaging module 10, and the second substrate region 302 extends beyond the plastic packaging module 10, which indicates that a width of the substrate module 30 is greater than that of the plastic packaging module 10. The second wiring layer 322 further includes a second solder pad 3222. The first conductive wiring pattern 3211 and the second solder pad 3222 of the second wiring layer 322 are located at the first substrate region 301 and the second substrate region 302, respectively. The second solder pad 3222 is exposed from the fourth surface 31B, which facilitates the connection of the external component on the second solder pad 3222. At this time, the electrical signal generated by the photosensitive chip 20 may be transmitted out from the fourth surface 31B.

The first multilayered wiring structure 32 is located at the first substrate region 301 and extends to the second substrate region 302. When the first multilayered wiring structure 32 includes the first wiring layer 321, at least one second wiring layer 322, and the third wiring layer 323, a portion of each of the second wiring layer 322 and the third wiring layer 323 is located in the first substrate region 301, and the remaining portion is located at the second substrate region 302. The first wiring layer 321 may only be located at the first substrate region 301. The second wiring layer 322 located at the first substrate region 301 may be fabricated simultaneously with the second wiring layer 322 located at the second substrate region 302. The third wiring layer 323 located at the first substrate region 301 may be fabricated simultaneously with the third wiring layer 323 located at the second substrate region 302.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A photoelectric packaging structure comprising:
a plastic packaging module comprising a packaging body, wherein the packaging body comprises a first surface and a second surface opposite to each other;
a photosensitive chip embedded in the packaging body and comprising a photosensitive area and a non-photosensitive area connected to each other, wherein the photosensitive area and the non-photosensitive area are exposed from the second surface, and the non-photosensitive area is provided with a connection pad; and a substrate module located on the second surface and comprising a dielectric layer and a first multilayered wiring structure formed in the dielectric layer, wherein the dielectric layer comprises a third surface facing the second surface and a fourth surface opposite the third surface, the first multilayered wiring structure comprises a first wiring layer and a second wiring layer stacked on the first wiring layer along a thickness direction of the substrate module;
wherein the first wiring layer is exposed from the third surface and comprises a first conductive portion and a first conductive wiring pattern, one side of the first conductive portion is in contact with the connection pad, at least a portion of the first conductive wiring pattern extends along a first direction, the second wiring layer comprises a second conductive portion and a second conductive wiring pattern, a portion of the second conductive wiring pattern is electrically connected to the second conductive portion, a portion of the second conductive wiring pattern is electrically connected to the first conductive wiring pattern, at least a portion of the second conductive wiring pattern extends along a second direction, the second conductive portion is electrically connected to another side of the first conductive portion, wherein the first direction and the second direction are perpendicular to the thickness direction;
at least the first conductive portion and the second conductive portion cooperatively constitute a first conductive channel extending along the thickness direction, such that the photosensitive chip is electrically connected to the first wiring layer and the second wiring layer through the connection pad and the first conductive channel.

2. The photoelectric packaging structure according to claim 1, wherein the first multilayered wiring structure further comprises a third wiring layer, the third wiring layer is located between the first wiring layer and the second wiring layer, the third wiring layer comprises a third conductive portion and a third conductive wiring pattern, two sides of the third conductive portion are electrically connected to the first conductive portion and the second conductive portion, respectively, to cooperative form the first conductive channel, the third conductive wiring pattern is electrically connected to the first conductive wiring pattern and the second conductive wiring pattern, and at least a portion of the third conductive wiring pattern extends both along the first direction or the second direction.

3. The photoelectric packaging structure according to claim 2, wherein the plastic packaging module further comprises a second conductive channel and a first solder pad, the second conductive channel is formed in the plastic packaging body and a portion of the dielectric layer, the second conductive channel extends through the first surface and the second surface, the first solder pad is exposed from the first surface and configured to connect to an external component, and two ends of the second conductive channel are connected to the first multilayered wiring structure and the first solder pad, respectively.

4. The photoelectric packaging structure according to claim 2, further comprising a first electronic component, wherein the packaging body further covers the first electronic component, and the first electronic component is connected to the first conductive wiring pattern.

5. The photoelectric packaging structure according to claim 1, wherein the plastic packaging module further comprises a second conductive channel and a first solder pad, wherein the second conductive channel is formed in the plastic packaging and extends through the first surface and the second surface, the first solder pad is exposed from the first surface and configured to connect to an external component, and two ends of the second conductive channel are connected to the first conductive wiring pattern and the first solder pad, respectively.

6. The photoelectric packaging structure according to claim 5, wherein the substrate module further comprises a second multilayered wiring structure, the second multilayered wiring structure is located in the dielectric layer and electrically connected to the first multilayered wiring structure, and the second multilayered wiring structure constitutes a second electronic component.

7. The photoelectric packaging structure according to claim 2, further comprising a solder ball provided on the first solder pad.

8. The photoelectric packaging structure according claim 2, wherein the connection pad, the first multilayered wiring structure, the second conductive channel, and the first solder pad are made of a same conductive material.

9. The photoelectric packaging structure according to claim 1, wherein the substrate module comprises a first substrate region and a second substrate region connected to each other, the first substrate region overlaps with the plastic packaging module, the second substrate region extends beyond the plastic packaging module, the first multilayered wiring structure is located in the first substrate region and extends to the second substrate region, the first conductive wiring pattern and the second conductive wiring pattern are located in the first substrate region;
the second wiring layer further comprises a second solder pad, the second solder pad is located in the second substrate region, and the second solder pad is exposed from the fourth surface and configured to connect to an external component.

10. The photoelectric packaging structure according to claim 1, wherein the first conductive wiring pattern extends both along the first direction and the second direction respectively, and the second conductive wiring pattern extends both along the first direction and the second direction.

11. A manufacturing method of a photoelectric packaging structure, comprising:
forming a packaging body which covers a photosensitive chip, wherein the packaging body comprises a first surface and a second surface opposite to each other, the photosensitive chip comprises a photosensitive area and a non-photosensitive area connected to each other, the photosensitive area and the non-photosensitive area are exposed from the second surface, and the non-photosensitive area is provided with a connection pad; forming a first insulating layer on the second surface and forming a first wiring layer in the first insulating layer, wherein the first insulating layer comprises a third surface facing the second surface, the first wiring layer is exposed from the third surface and comprises a first conductive portion and a first conductive wiring pattern, one side of the first conductive portion is in contact with the connection pad, at least a portion of the first conductive wiring pattern extends along a first direction, wherein the first direction is perpendicular to a thickness direction of the first insulating layer; and forming a second insulating layer on the first insulating layer and forming a second wiring layer in the second insulating layer, wherein the second wiring layer comprises a second conductive portion and a second conductive wiring pattern, a portion of the second conductive wiring pattern is electrically connected to the second conductive portion, a portion of the second conductive wiring pattern is electrically connected to the first conductive wiring pattern, at least a portion of the second conductive wiring pattern extends along a second direction, the second conductive portion is electrically connected to another side of the first conductive portion, at least the first conductive portion and the second conductive portion cooperatively constitute a first conductive channel extending along the thickness direction, such that the photosensitive chip is electrically connected to the first wiring layer and the second wiring layer through the connection pad and the first conductive channel, wherein the second direction is perpendicular to the thickness direction.

12. The manufacturing method according to claim 11, wherein before forming the second insulating layer and the second wiring layer, the manufacturing method further comprises:
forming a third insulating layer on the first insulating layer and forming a third wiring layer in the third insulating layer, wherein the third wiring layer comprises a third conductive portion and a third conductive wiring pattern; wherein after forming the second insulating layer and the second wiring layer, two sides of the third conductive portion are electrically connected to the first conductive portion and the second conductive portion, respectively, to cooperatively form the first conductive channel, the third conductive wiring pattern is electrically connected to the first conductive wiring pattern and the second conductive wiring pattern, and at least a portion of the third conductive wiring pattern extends along the first direction or the second direction.

13. The manufacturing method according to claim 12, further comprising:
defining a hollow channel in the packaging body by laser, wherein the hollow channel comprises a first channel portion and a second channel portion connected to each other, the first channel portion extends through the first surface and the second surface and extends to the first multilayered wiring structure, and the second channel portion is located on the first surface; and filling a conductive material in the first channel portion and the second channel portion and solidifying the conductive material to obtain a second conductive channel and a first solder pad, respectively, wherein the first solder pad is exposed from the first surface and configured to connect to an external component, two ends of the second conductive channel are connected to the first multilayered wiring structure and the first solder pad, respectively.

14. The manufacturing method according to claim 13, wherein the packaging body further covers a first electronic component; after forming the first wiring layer, the first electronic component is connected to the first conductive wiring pattern.

15. The manufacturing method according to claim 12, further comprising:
defining a hollow channel in the packaging body by laser, wherein the hollow channel comprises a first channel portion and a second channel portion connected to each other, the first channel portion extends through the first surface and the second surface, and the second channel portion is located on the first surface; and filling a conductive material in the first channel portion and the second channel portion and solidifying the conductive material to obtain a second conductive channel and a first solder pad, respectively, wherein the first solder pad is exposed from the first surface and configured to connect to an external component, two ends of the second conductive channel are connected to the first conductive wiring pattern and the first solder pad, respectively.

16. The manufacturing method according to claim 15, wherein when forming the first wiring layer, the manufacturing method further comprises forming a fourth wiring layer in the first insulating layer; wherein when forming the third wiring layer, the manufacturing method further comprises forming a fifth wiring layer in the third insulating layer, wherein at least the fourth wiring layer and the fifth wiring layer constitute a second electronic component, and the second electronic component is electrically connected to the first wiring layer, the second wiring layer, or the third wiring layer.

17. A camera module comprising:
a lens assembly; and a photoelectric packaging structure according to claim 1, wherein the lens assembly is disposed on a side of the substrate module of the photoelectric packaging structure away from the plastic packaging module.
